(19) United States
(12) Patent Application Publication
(10) Pub. No.: US 2025/0326893 A1
(43) Pub. Date: Oct. 23, 2025

(54) RESIN COMPOSITION, PREPREG, LAMINATE, RESIN FILM, PRINTED WIRING BOARD, AND SEMICONDUCTOR PACKAGE

(71) Applicant: Resonac Corporation, Tokyo (JP)

(72) Inventors: Tsutomu SATO, Tokyo (JP); Norihiko SAKAMOTO, Tokyo (JP); Kohei OTSUKA, Tokyo (JP); Takayo KITAJIMA, Tokyo (JP); Shinji SHIMAOKA, Tokyo (JP)

(21) Appl. No.: 18/859,491

(22) PCT Filed: Jun. 15, 2023
(86) PCT No.: PCT/JP2023/022177

§ 371 Date: Oct. 23, 2024

(30) Foreign Application Priority Data
Jun. 17, 2022 (JP) 2022-098179

(51) Int. Cl. C08G 73/12; B32B 27/28; B32B 27/38

(52) U.S. Cl. CPC C08G 73/12; B32B 27/281; B32B 27/38

(57) ABSTRACT

A resin composition containing (A) a resin containing a structure derived from a maleimide resin (a) having one or more N-substituted maleimide groups, and a structure derived from an amine compound (b) having one or more amino groups, and (B) a maleimide resin having three or more N-substituted maleimide groups, and a prepreg, a laminate, a resin film, a printed wiring board, and a semiconductor package, using the resin composition.

### TECHNICAL FIELD

The present embodiment relates to a resin composition, a prepreg, a laminate, a resin film, a printed wiring board, and a semiconductor package.

### BACKGROUND ART

With the trend toward smaller size and higher performance of electronic devices in recent years, a printed wiring board is being increased in wiring density and integration. Accordingly, a printed wiring board is demanded to have higher reliability than the ordinary products.

The demanded characteristics of the insulating layer of the printed wiring board include good heat resistance. In particular, due to the growing awareness of environmental issues in recent years, a semiconductor chip mounting process that does not use lead-free solder has become mainstream, and the insulating layer is demanded to have heat resistance that is applicable to the mounting at a higher reflow temperature.

The insulating layer of the printed wiring board uses, for example, a thermosetting resin, such as a maleimide resin and an epoxy resin. A cured product using a maleimide resin has an advantage that better heat resistance than a cured product using an epoxy resin can be easily obtained, but a maleimide resin has problems of a higher curing temperature required, low solvent solubility, poor handleability, and the like.

PTL 1 describes a thermosetting resin composition containing a resin composition having an unsaturated maleimide group obtained through reaction of a maleimide compound (a) having at least two N-substituted maleimide groups in one molecule, and an amine compound (b) having at least two primary amino groups in one molecule, and the like.

### CITATION LIST

### Patent Literature

PTL 1: JP 2013-063136 A

### SUMMARY OF INVENTION

### Technical Problem

The technique of PTL 1 can provide a thermosetting resin composition that has good resin curability, i.e., not requiring a high-temperature and long-time treatment in laminating a prepreg, and also has good curability and storage stability of the varnish and prepreg, and excellent chemical resistance, heat resistance, and adhesiveness.

In the production process of the printed wiring board, a desmear treatment is performed for the purpose of removing residues after drilling the insulating layer, and the like. When the insulating layer is excessively dissolved through the desmear treatment, there may be cases where the hole diameters of the through holes and the like are changed from the prescribed size, and the adhesiveness to the conductor layer is decreased. Accordingly, the insulating layer is demanded to have desmear resistance that suppresses the excessive dissolution in the desmear treatment.

The wiring density in the field of printed wiring boards is being conspicuously increased in recent years, and higher desmear resistance than ever is being demanded. According to the investigations by the present inventors, the technique of PTL 1 has room for improvement in desmear resistance.

In view of the current situation, a problem to be solved by the present embodiment is to provide a resin composition that is excellent in desmear resistance, and a prepreg, a laminate, a resin film, a printed wiring board, and a semiconductor package, using the resin composition.

### Solution to Problem

The present inventors have made earnest studies for solving the problem, and have found that the present embodiment described below can solve the problem.

Specifically, the present embodiment relates to the following items [1] to [12].
[1] A resin composition containing
   (A) a resin containing a structure derived from a maleimide resin (a) having one or more N-substituted maleimide groups, and a structure derived from an amine compound (b) having one or more amino groups, and
   (B) a maleimide resin having three or more N-substituted maleimide groups.
[2] The resin composition according to the item [1], wherein the amine compound (b) having one or more amino groups is a siloxane compound having one or more amino groups.
[3] The resin composition according to the item [1] or [2], wherein the component (B) is a maleimide resin having three or more N-substituted maleimide groups that are bonded to an aromatic ring.
[4] The resin composition according to the item [3], wherein the maleimide resin having three or more N-substituted maleimide groups that are bonded to the aromatic ring is a maleimide resin represented by the following general formula (B-1).

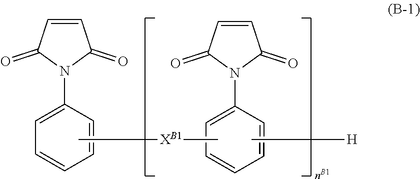

(In the formula, X^{B1} represents a divalent hydrocarbon group having 1 to 20 carbon atoms, and n^{B1} represents an integer of 2 to 5.)
[5] The resin composition according to the item [4], wherein, in the general formula (B-1), X^{B1} represents an alkylene group having 1 to 5 carbon atoms or an alkylidene group having 2 to 5 carbon atoms.
[6] The resin composition according to any one of the items [1] to [5], wherein the resin composition has a ratio of the content of the component (B) with respect to the content of the component (A) (component (B)/component (A)) based on mass of 0.4 to 10.
[7] The resin composition according to any one of the items [1] to [6], wherein the resin composition further contains (C) an epoxy resin.
[8] A prepreg including the resin composition according to any one of the items [1] to [7] or a semi-cured product of the resin composition.
[9] A laminate including a cured product of the resin composition according to any one of the items [1] to [7] and a metal foil.
[10] A resin film including the resin composition according to any one of the items [1] to [7] or a semi-cured product of the resin composition.

[11] A printed wiring board including a cured product of the resin composition according to any one of the items [1] to [7].
[12] A semiconductor package including the printed wiring board according to the item and a semiconductor device.

### ADVANTAGEOUS EFFECTS OF INVENTION

The present embodiment can provide a resin composition that is excellent in desmear resistance, and a prepreg, a laminate, a resin film, a printed wiring board, and a semiconductor package, using the resin composition.

### DESCRIPTION OF EMBODIMENTS

In the description herein, the numerical range shown by “to” means a range that includes the numerical values shown before and after “to” as the minimum value and the maximum value, respectively.

For example, the expression of a numerical range of “X to Y” (wherein X and Y each represent a real number) means a numerical range of X or more and Y or less. In the description herein, the description “X or more” means X and a numerical value exceeding X. In the description herein, the description “Y or less” means Y and a numerical value of less than Y.

The lower limit value and the upper limit value of the numerical range described in the description herein can be optionally combined with the other upper limit value and the other lower limit value of the numerical range, respectively.

In the numerical range described in the description herein, the lower limit values and the upper limit values of the numerical ranges each can be replaced by the values described in the examples.

For each of the components and the materials exemplified in the description herein, one kind thereof may be used alone, or two or more kinds thereof may be used in combination, unless otherwise indicated.

In the description herein, the content of the component of the resin composition in the case where multiple kinds of substances corresponding to the component exist in the resin composition means the total amount of the multiple substances existing in the resin composition, unless otherwise indicated.

In the description herein, the “solid content” means components other than a solvent, and includes materials in the form of liquid, jelly, and wax at room temperature. In the description herein, the room temperature means 25° C.

The number average molecular weight (Mn) in the description herein means a value that is measured in terms of polystyrene conversion through gel permeation chromatography (GPC). Specifically, the weight average molecular weight (Mw) in the description herein can be measured by the method described in the examples.

The “semi-cured product” in the description herein has the same meaning as a resin composition in B-stage defined in JIS K6800(1985), and the “cured product” therein has the same meaning as a resin composition in C-stage defined in JIS K6800(1985).

The functional mechanisms described in the description herein are estimation, and do not limit the mechanisms that achieves the effects of the present embodiment.

An embodiment including an optional combination of the items described in the description herein is also encompassed in the present embodiment.

### Resin Composition

The resin composition of the present embodiment is a resin composition containing
(A) a resin containing a structure derived from a maleimide resin (a) having one or more N-substituted maleimide groups, and a structure derived from an amine compound (b) having one or more amino groups (which may be hereinafter referred to as a “modified maleimide resin (A)”), and
(B) a maleimide resin having three or more N-substituted maleimide groups (which may be hereinafter referred to as a “polymaleimide resin (B)”).

In the description herein, these components may be abbreviated as the component (A), the component (B), and the like, and the other components may also be abbreviated in the same manner.

The components that can be contained in the resin composition of the present embodiment will be described in order below.

### Modified Maleimide Resin (A)

The modified maleimide resin (A) is not particularly limited, as long as being a resin containing a structure derived from a maleimide resin (a) having one or more N-substituted maleimide groups, and a structure derived from an amine compound (b) having one or more amino groups.

One kind of the modified maleimide resin (A) may be used alone, or two or more kinds thereof may be used in combination.

In the following description, the maleimide resin (a) having one or more N-substituted maleimide groups may be referred simply to as a “maleimide resin (a1)”. In the following description, the amine compound (b) having one or more amino groups may be referred simply to as an “amine compound (a2)”.

Structure derived from Maleimide Resin (a1)

The structure derived from the maleimide resin (a1) is preferably a structure that is formed through the Michael addition reaction of at least one N-substituted maleimide group of the N-substituted maleimide groups of the maleimide resin (a1) with the amino group of the amine compound (a2).

One kind of the structure derived from the maleimide resin (a1) alone may be contained in the modified maleimide resin (A), or two or more kinds thereof may be contained therein.

The content of the structure derived from the maleimide resin (a1) in the modified maleimide resin (A) is not particularly limited, and is preferably 20 to 90% by mass, more preferably 30 to 80% by mass, and further preferably 40 to 70% by mass.

In the case where the content of the structure derived from the maleimide resin (a1) in the modified maleimide resin (A) is in the range, there is a tendency that the heat resistance, the dielectric characteristics, and the handleability in forming into a resin film are further improved.

### Maleimide Resin (a1)

The maleimide resin (a1) is not particularly limited, as long as being a maleimide resin having one or more N-substituted maleimide groups.

The maleimide resin (a1) is preferably a bismaleimide resin having two N-substituted maleimide groups or a polymaleimide resin having three or more N-substituted maleimide groups, and more preferably an aromatic bismaleimide resin having two N-substituted maleimide groups that are bonded to the aromatic ring or an aromatic polymaleimide resin having three or more N-substituted maleimide groups that are bonded to the aromatic ring, from the standpoint of the adhesiveness to a conductor and the heat resistance.

Examples of the bismaleimide resin that is preferred as the maleimide resin (a1) include a maleimide resin represented by the following general formula (a1-1).

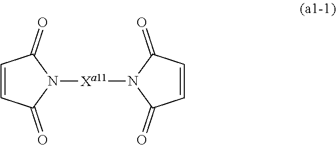

(In the formula, X^{a11} represents a divalent organic group.)

In the general formula (a1-1), X^{a11} represents a divalent organic group.

Examples of the divalent organic group represented by X^{a11} in the general formula (a1-1) include a divalent group represented by the following general formula (a1-2), a divalent group represented by the following general formula (a1-3), and a divalent group represented by the following general formula (a1-4).

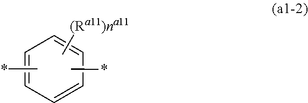

(In the formula, R^{a11} represents an aliphatic hydrocarbon group having 1 to 5 carbon atoms or a halogen atom, n^{a11} represents an integer of 0 to 4, and * represents a bonding site.)

Examples of the aliphatic hydrocarbon group having 1 to 5 carbon atoms represented by R^{a11} in the general formula (a1-2) include an alkyl group having 1 to 5 carbon atoms, such as a methyl group, an ethyl group, a n-propyl group, an isopropyl group, a n-butyl group, an isobutyl group, a t-butyl group, and a n-pentyl group; an alkenyl group having 2 to 5 carbon atoms: and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and further preferably a methyl group.

Examples of the halogen atom include a fluorine atom, a chlorine atom, a bromine atom, and an iodine atom.

In the general formula (a1-2), n^{a11} represents an integer of 0 to 4, and preferably represents an integer of 0 to 2, more preferably 0 or 1, and further preferably 0, from the standpoint of the availability.

In the case where n^{a11} represents an integer of 2 or more, multiple groups or atoms represented by R^{a11} may be the same as or different from each other.

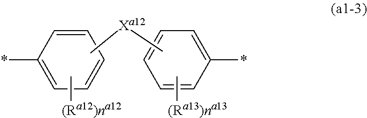

(In the formula, R^{a12} and R^{a13} each independently represent an aliphatic hydrocarbon group having 1 to 5 carbon atoms or a halogen atom, X^{a12} represents an alkylene group having 1 to 5 carbon atoms, an alkylidene group having 2 to 5 carbon atoms, an ether group, a sulfide group, a sulfonyl group, a carbonyloxy group, a keto group, a single bond, or a divalent group represented by the following general formula (a1-3-1), n^{a12} and n^{a13} each independently represent an integer of 0 to 4, and * represents a bonding site.)

Examples of the aliphatic hydrocarbon group having 1 to 5 carbon atoms represented by R^{a12} and R^{a13} in the general formula (a1-3) include an alkyl group having 1 to 5 carbon atoms, such as a methyl group, an ethyl group, a n-propyl group, an isopropyl group, a n-butyl group, an isobutyl group, a t-butyl group, and a n-pentyl group: an alkenyl group having 2 to 5 carbon atoms; and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and further preferably a methyl group or an ethyl group.

Examples of the halogen atom include a fluorine atom, a chlorine atom, a bromine atom, and an iodine atom.

Examples of the alkylene group having 1 to 5 carbon atoms represented by X^{a12} in the general formula (a1-3) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and further preferably a methylene group.

Examples of the alkylidene group having 2 to 5 carbon atoms represented by X^{a12} in the general formula (a1-3) include an ethylidene group, a propylidene group, an isopropylidene group, a butylidene group, an isobutylidene group, a pentylidene group, and an isopentylidene group. Among these, an alkylidene group having 2 to 4 carbon atoms is preferred, an alkylidene group having 2 or 3 carbon atoms is more preferred, and an isopropylidene group is further preferred.

n^{a12} and n^{a13} in the general formula (a1-3) each independently represent an integer of 0 to 4.

In the case where n^{a12} or n^{a13} represents an integer of 2 or more, multiple groups or atoms represented by R^{a12} or R^{a13} may be the same as or different from each other.

The divalent group represented by the general formula (a1-3-1) represented by X^{a12} in the general formula (a1-3) is as follows.

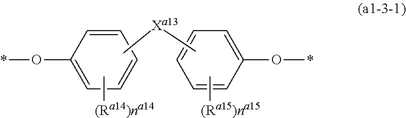

(In the formula, R^{a14} and R^{a15} each independently represent an aliphatic hydrocarbon group having 1 to 5 carbon atoms or a halogen atom, X^{a13} represents an alkylene group having 1 to 5 carbon atoms, an alkylidene group having 2 to 5 carbon atoms, an ether group, a sulfide group, a sulfonyl group, a carbonyloxy group, a keto group, or a single bond, n^{a14} and n^{a15} each independently represent an integer of 0 to 4, and * represents a bonding site.)

Examples of the aliphatic hydrocarbon group having 1 to 5 carbon atoms represented by R^{a14} and R^{a15} in the general formula (a1-3-1) include an alkyl group having 1 to 5 carbon atoms, such as a methyl group, an ethyl group, a n-propyl group, an isopropyl group, a n-butyl group, an isobutyl group, a t-butyl group, and a n-pentyl group: an alkenyl group having 2 to 5 carbon atoms: and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and further preferably a methyl group.

Examples of the halogen atom include a fluorine atom, a chlorine atom, a bromine atom, and an iodine atom.

Examples of the alkylene group having 1 to 5 carbon atoms represented by X^{a13} in the general formula (a1-3-1) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and further preferably a methylene group.

Examples of the alkylidene group having 2 to 5 carbon atoms represented by X^{a13} in the general formula (a1-3-1) include an ethylidene group, a propylidene group, an isopropylidene group, a butylidene group, an isobutylidene group, a pentylidene group, and an isopentylidene group. Among these, an alkylidene group having 2 to 4 carbon atoms is preferred, an alkylidene group having 2 or 3 carbon atoms is more preferred, and an isopropylidene group is further preferred.

Among the aforementioned options, X^{a13} in the general formula (a1-3-1) preferably represents an alkylidene group having 2 to 5 carbon atoms, more preferably an alkylidene group having 2 to 4 carbon atoms, and further preferably an isopropylidene group.

n^{a14} and n^{a15} in the general formula (a1-3-1) each independently represent an integer of 0 to 4, and preferably represent an integer of 0 to 2, more preferably 0 or 1, and further preferably 0, from the standpoint of the availability.

In the case where n^{a14} or n^{a15} represents an integer of 2 or more, multiple groups or atoms represented by R^{a14} or R^{a15} may be the same as or different from each other.

Among the aforementioned options, X^{a12} in the general formula (a1-3) preferably represents an alkylene group having 1 to 5 carbon atoms, an alkylidene group having 2 to 5 carbon atoms, or a divalent group represented by the general formula (a1-3-1), and more preferably a divalent group represented by the general formula (a1-3-1).

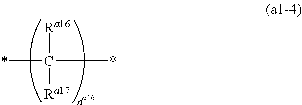

(In the formula, R^{a16} and R^{a17} each independently represent a hydrogen atom or an aliphatic hydrocarbon group having 1 to 5 carbon atoms, n^{a16} represents an integer of 1 to 8, and * represents a bonding site.)

Examples of the aliphatic hydrocarbon group having 1 to 5 carbon atoms represented by R^{a16} and R^{a17} in the general formula (a1-4) include an alkyl group having 1 to 5 carbon atoms, such as a methyl group, an ethyl group, a n-propyl group, an isopropyl group, a n-butyl group, an isobutyl group, a t-butyl group, and a n-pentyl group: an alkenyl group having 2 to 5 carbon atoms: and an alkynyl group having 2 to 5 carbon atoms. The aliphatic hydrocarbon group having 1 to 5 carbon atoms may be either linear or branched.

n^{a16} in the general formula (a1-4) represents an integer of 1 to 8, preferably an integer of 1 to 5, more preferably an integer of 1 to 3, and further preferably 1. In the case where n^{a16} represents an integer of 2 or more, multiple groups or atoms represented by R^{a16} or R^{a17} may be the same as or different from each other.

In the maleimide resin represented by the general formula (a1-1) described above, a maleimide resin having a divalent group represented by the general formula (a1-3) as X^{a11} is preferred, and a maleimide resin having a divalent group represented by the general formula (a1-3-1) as X^{a12} in the general formula (a1-3) is more preferred.

Examples of the bismaleimide resin include N,N′-ethylenebismaleimide, N,N′-hexamethylenebismaleimide, N,N′-(1,3-phenylene) bismaleimide, N,N′-[1,3-(2-methylphenylene)]bismaleimide, N,N′-[1,3-(4-methylphenylene)]bismaleimide, N,N′-(1,4-phenylene) bismaleimide, bis(4-maleimidophenyl) methane, bis(3-methyl-4-maleimidophenyl) methane, 3,3′-dimethyl-5,5′-diethyl-4,4′-diphenylmethanebismaleimide, bis(4-maleimidophenyl)ether, bis(4-maleimidophenyl)sulfone, bis(4-maleimidophenyl) sulfide, bis(4-maleimidophenyl)ketone, bis(4-maleimidocyclohexyl) methane, 1,4-bis 4-maleimidophenyl) cyclohexane, 1,4-bis(maleimidomethyl)cyclohexane, 1,4-bis(maleimidomethyl)benzene, 1,3-bis(4-maleimidophenoxy)benzene, 1,3-bis(3-maleimidophenoxy) benzene, bis[4-(3-maleimidophenoxy)phenyl]methane, bis[4-(4-maleimidophenoxy) phenyl]methane, 1.1-bis[4-(3-maleimidophenoxy)phenyl]ethane. 1,1-bis[4-(4-maleimidophenoxy)phenyl]ethane, 1,2-bis[4-(3-maleimidophenoxy)phenyl]ethane, 1,2-bis[4-(4-maleimidophenoxy)phenyl]ethane, 2,2-bis[4-(3-maleimidophenoxy) phenyl]propane, 2,2-bis[4-(4-maleimidophenoxy)phenyl]propane, 2,2-bis[4-(3-maleimidophenoxy)phenyl]butane, 2,2-bis[4-(4-maleimidophenoxy)phenyl]butane, 2,2-bis[4-(3-maleimidophenoxy)phenyl]-1,1,1,3,3,3-hexafluoropropane, 2,2-bis[4-(4-maleimidophenoxy) phenyl]-1,1,1,3,3,3-hexafluoropropane, 4,4′-bis(3-maleimidophenoxy) biphenyl, 4,4′-bis(4-maleimidophenoxy)biphenyl, bis[4-(3-maleimidophenoxy) phenyl] ketone, bis[4-(4-maleimidophenoxy)phenyl] ketone, bis(4-maleimidophenyl) disulfide, bis[4-(3-maleimidophenoxy)phenyl] sulfide, bis[4-(4-maleimidophenoxy) phenyl] sulfide, bis[4-(3-maleimidophenoxy)phenyl] sulfoxide, bis[4-(4-maleimidophenoxy) phenyl] sulfoxide, bis[4-(3-maleimidophenoxy)phenyl] sulfone, bis[4-(4-maleimidophenoxy) phenyl] sulfone, bis[4-(3-maleimidophenoxy)phenyl] ether, bis[4-(4-maleimidophenoxy) phenyl] ether, 1,4-bis[4-(4-maleimidophenoxy)-α,α-dimethylbenzyl]benzene, 1,3-bis[4-(4-maleimidophenoxy)-α,α-dimethylbenzyl]benzene, 1,4-bis[4-(3-maleimidophenoxy)-α,α-dimethylbenzyl]benzene, 1,3-bis[4-(3-maleimidophenoxy)-α,α-dimethylbenzyl]benzene, 1,4-bis[4-(4-maleimidophenoxy)-3,5-dimethyl-α,α-dimethylbenzyl]benzene, 1,3-bis[4-(4-maleimidophenoxy)-3,5-dimethyl-α,α-dimethylbenzyl]benzene, 1,4-bis[4-(3-maleimidophenoxy)-3,5-dimethyl-α,α-dimethylbenzyl]benzene, 1,3-bis[4-(3-maleimidophenoxy)-3,5-dimethyl-α,α-dimethylbenzyl]benzene, and an aromatic bismaleimide having an indane skeleton. Among these. 3,3′-dimethyl-5,5′-diethyl-4,4′-diphenylmethanebismaleimide, 2,2-bis[4-(4-maleimidophenoxy)phenyl]propane, and bis(4-maleimidophenyl)methane are preferred.

The descriptions relating to the polymaleimide resin that is preferred as the maleimide resin (a1) are the same as the descriptions relating to “(B) the maleimide resin having three or more N-substituted maleimide groups” described later, and the preferred embodiments thereof are also the same.

Structure Derived from Amine Compound (a2)

The structure derived from the amine compound (a2) is preferably a structure that is formed through the Michael addition reaction of the at least one amino group of the amine compound (a2) with the N-substituted maleimide group of the maleimide resin (a1).

One kind of the structure derived from the amine compound (a2) alone may be contained in the modified maleimide resin (A), or two or more kinds thereof may be contained therein.

The content of the structure derived from the amine compound (a2) in the modified maleimide resin (A) is not particularly limited, and is preferably 10 to 80% by mass, more preferably 20 to 70% by mass, and further preferably 30 to 60% by mass.

In the case where the content of the structure derived from the amine compound (a2) in the modified maleimide resin (A) is in the range, there is a tendency that the dielectric characteristics, the heat resistance, the flame retardancy, and the glass transition temperature are further improved.

### Amine Compound (a2)

The amine compound (a2) is not particularly limited, as long as being an amine compound having one or more amino groups.

The amine compound (a2) is preferably an amine compound having two or more amino groups, and more preferably a diamine compound having two amino groups. The amine compound (a2) is preferably a siloxane compound having one or more amino groups, more preferably a siloxane compound having two or more amino groups, and further preferably a siloxane compound having two amino groups, from the standpoint of the low thermal expansion.

The amino group of the amine compound (a2) is preferably a primary amino group.

The amine compound (a2) is preferably a diamine compound represented by the following general formula (a2-1).

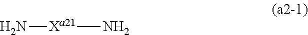

(In the formula, X^{a21} represents a divalent organic group.)

X^{a21} in the general formula (a2-1) preferably represents a divalent group represented by the following general formula (a2-2).

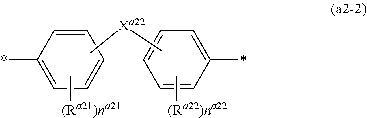

(In the formula, R^{a21} and R^{a22} each independently represent an aliphatic hydrocarbon group having 1 to 5 carbon atoms, an alkoxy group having 1 to 5 carbon atoms, a hydroxy group, or a halogen atom, X^{a22} represents an alkylene group having 1 to 5 carbon atoms, an alkylidene group having 2 to 5 carbon atoms, an ether group, a sulfide group, a sulfonyl group, a carbonyloxy group, a keto group, a fluorenylene group, a single bond, or a divalent group represented by the following general formula (a2-2-1) or the following general formula (a2-2-2), n^{a21} and n^{a22} each independently represent an integer of 0 to 4, and * represents a bonding site.)

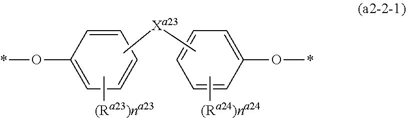

(In the formula, R^{a23} and R^{a24} each independently represent an aliphatic hydrocarbon group having 1 to 5 carbon atoms or a halogen atom, X^{a23} represents an alkylene group having 1 to 5 carbon atoms, an alkylidene group having 2 to 5 carbon atoms, a m-phenylenediisopropylidene group, a p-phenylenediisopropylidene group, an ether group, a sulfide group, a sulfonyl group, a carbonyloxy group, a keto group, or a single bond, n^{a23} and n^{a24} each independently represent an integer of 0 to 4, and * represents a bonding site.)

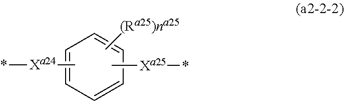

(In the formula, R^{a25} represents an aliphatic hydrocarbon group having 1 to 5 carbon atoms or a halogen atom, X^{a24} and X^{a25} each independently represent an alkylene group having 1 to 5 carbon atoms, an alkylidene group having 2 to 5 carbon atoms, an ether group, a sulfide group, a sulfonyl group, a carbonyloxy group, a keto group, or a single bond, n^{a25} represents an integer of 0 to 4, and * represents a bonding site.)

Examples of the aliphatic hydrocarbon group having 1 to 5 carbon atoms represented by R^{a21}, R^{a22}, R^{a23}, R^{a24}, and R^{a25} in the general formula (a2-2), the general formula (a2-2-1), and the general formula (a2-2-2) include an alkyl group having 1 to 5 carbon atoms, such as a methyl group, an ethyl group, an-propyl group, an isopropyl group, a n-butyl group, an isobutyl group, a t-butyl group, and a n-pentyl group: an alkenyl group having 2 to 5 carbon atoms: and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and further preferably a methyl group or an ethyl group.

Examples of the halogen atom include a fluorine atom, a chlorine atom, a bromine atom, and an iodine atom.

Examples of the alkylene group having 1 to 5 carbon atoms represented by X^{a22} in the general formula (a2-2), X^{a23} in the general formula (a2-2-1), and X^{a24} and X^{a25} in the general formula (a2-2-2) include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and further preferably a methylene group.

Examples of the alkylidene group having 2 to 5 carbon atoms represented by X^{a22} in the general formula (a2-2), X^{a23} in the general formula (a2-2-1), and X^{a24} and X^{a25} in the general formula (a2-2-2) include an ethylidene group, a propylidene group, an isopropylidene group, a butylidene group, an isobutylidene group, a pentylidene group, and an isopentylidene group. The alkylidene group having 2 to 5 carbon atoms is preferably an alkylidene group having 2 to 4 carbon atoms, more preferably an alkylidene group having 2 or 3 carbon atoms, and further preferably an isopropylidene group.

n^{a21} and n^{a22} in the general formula (a2-2) each independently represent an integer of 0 to 4, and preferably represent an integer of 0 to 3, more preferably an integer of 0 to 2, and further preferably 0 or 2, from the standpoint of the availability.

In the case where n^{a21} or n^{a22} represents an integer of 2 or more, multiple groups or atoms represented by R^{a21} or R^{a22} may be the same as or different from each other.

n^{a23} and n^{a24} in the general formula (a2-2-1) each independently represent an integer of 0 to 4, and preferably represent an integer of 0 to 2, more preferably 0 or 1, and further preferably 0, from the standpoint of the availability.

In the case where n^{a23} or n^{a24} represents an integer of 2 or more, multiple groups or atoms represented by R^{a23} or R^{a24} may be the same as or different from each other.

n^{a25} in the general formula (a2-2-2) represents an integer of 0 to 4, and preferably represent an integer of 0 to 2, more preferably 0 or 1, and further preferably 0, from the standpoint of the availability.

In the case where n^{a25} represents an integer of 2 or more, multiple groups or atoms represented by R^{a25} may be the same as or different from each other.

X^{a21} in the general formula (a2-1) may be a divalent group containing a structure represented by the following general formula (a2-3), and may be a divalent group represented by the following general formula (a2-4).

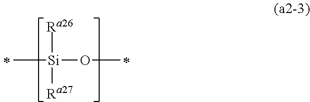

(In the formula, R^{a26} and R^{a27} each independently represent an aliphatic hydrocarbon group having 1 to 5 carbon atoms, a phenyl group, or a substituted phenyl group, and * represents a bonding site.)

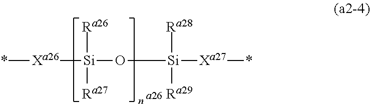

(In the formula, R^{a26} and R^{a27} are the same as in the general formula (a2-3), R^{a28} and R^{a29} each independently represent an aliphatic hydrocarbon group having 1 to 5 carbon atoms, a phenyl group, or a substituted phenyl group, X^{a26} and X^{a27} each independently represent a divalent organic group, n^{a26} represents an integer of 2 to 100, and * represents a bonding site.)

Examples of the aliphatic hydrocarbon group having 1 to 5 carbon atoms represented by R^{a26} to R^{a29} in the general formulae (a2-3) and (a2-4) include an alkyl group having 1 to 5 carbon atoms, such as a methyl group, an ethyl group, a n-propyl group, an isopropyl group, a n-butyl group, an isobutyl group, at-butyl group, and a n-pentyl group: an alkenyl group having 2 to 5 carbon atoms: and an alkynyl group having 2 to 5 carbon atoms. The aliphatic hydrocarbon group having 1 to 5 carbon atoms may be either linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and further preferably a methyl group.

Examples of the substituent of the phenyl group in the substituted phenyl group represented by R^{a26} to R^{a29} include the aliphatic hydrocarbon group having 1 to 5 carbon atoms described above.

Examples of the divalent organic group represented by X^{a26} and X^{a27} include an alkylene group, an alkenylene group, an alkynylene group, an arylene group, —O—, and a divalent linking group including a combination of these groups.

Examples of the alkylene group include an alkylene group having 1 to 10 carbon atoms, such as a methylene group, an ethylene group, and a propylene group.

Examples of the alkenylene group include an alkenylene group having 2 to 10 carbon atoms.

Examples of the alkynylene group include an alkynylene group having 2 to 10 carbon atoms.

Examples of the arylene group include an arylene group having 6 to 20 carbon atoms, such as a phenylene group and a naphthylene group.

Among these, X^{a26} and X^{a27} each preferably represent an alkylene group or an arylene group, and more preferably represent an alkylene group.

n^{a26} represents an integer of 2 to 100, preferably an integer of 2 to 50, more preferably an integer of 3 to 40, and further preferably an integer of 5 to 30. In the case where n^{a26} represents an integer of 2 or more, multiple groups or atoms represented by R^{a26} or R^{a27} may be the same as or different from each other.

Examples of the amine compound (a2) include an aromatic diamine compound, such as 4,4′-diaminodiphenylmethane, 3,3′-dimethyl-4,4′-diaminodiphenylmethane, 3,3′-diethyl-4,4′-diaminodiphenylmethane, 4,4′-diaminodiphenyl ether, 4,4′-diaminodiphenyl sulfone, 3,3′-diaminodiphenyl sulfone, 4,4′-diaminodiphenyl ketone, 4,4′-diaminobiphenyl, 3,3′-dimethyl-4,4′-diaminobiphenyl, 2,2′-dimethyl-4,4′-diaminobiphenyl, 3,3′-dihydroxy benzidine, 2,2-bis (3-amino-4-hydroxyphenyl)propane, 3,3′-dimethyl-5,5′-diethyl-4,4′-diaminodiphenylmethane, 2,2-bis(4-aminophenyl)propane, 2,2-bis[4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 1,3-bis[1-[4-(4-aminophenoxy)phenyl]-1-methylethyl]benzene, 1,4-bis[1-[4-(4-aminophenoxy)phenyl]-1-methylethyl]benzene, 4,4′-[1,3-phenylenebis(1-methylethylidene)]bisaniline, 4,4′-[1,4-phenylenebis (1-methylethylidene)]bisaniline, 3,3′-[1,3-phenylenebis(1-methylethylidene)]bisaniline, bis[4-(4-aminophenoxy)phenyl] sulfone, bis[4-(3-aminophenoxy)phenyl] sulfone, and 9,9-bis(4-aminophenyl)fluorene: and a siloxane compound having two amino groups.

In the description herein, the “aromatic diamine compound” means a compound having two amino groups that are bonded directly to the aromatic ring.

Among these, the amine compound (a2) is preferably 4,4′-diaminodiphenylmethane, 3,3′-dimethyl-4,4′-diaminodiphenylmethane, 3,3′-diethyl-4,4′-diaminodiphenylmethane, 2,2-bis[4-(4-aminophenoxy)phenyl]propane, 4,4′-[1,3-phenylenebis(1-methylethylidene)]bisaniline, or 4,4′-[1,4-phenylenebis(1-methylethylidene)]bisaniline, and more preferably 3,3′-diethyl-4,4′-diaminodiphenylmethane, from the standpoint of providing the excellent solubility in an organic solvent, the excellent reactivity, the excellent heat resistance, the excellent dielectric characteristics, and the excellent low water absorption. A siloxane compound having two primary amino groups is preferred from the standpoint of the low thermal expansion.

The siloxane compound having two primary amino groups is preferably a siloxane compound having primary amino groups at both ends thereof.

The primary amino group equivalent of the siloxane compound having two primary amino groups is not particularly limited, and is preferably 300 to 2,000 g/mol, more preferably 400 to 1,500 g/mol, and further preferably 500 to 1,000 g/mol.

The equivalent ratio of the total equivalent (Ta2) of the groups derived from the amino group of the amine compound (a2) and the total equivalent (Ta1) of the groups derived from the N-substituted maleimide group of the maleimide resin (a1) (Ta2/Ta1) in the modified maleimide resin (A) is not particularly limited, and is preferably 0.05 to 10, more preferably 1 to 8, and further preferably 3 to 7, from the standpoint of the dielectric characteristics, the heat resistance, the flame retardancy, and the glass transition temperature. The groups derived from the amino group of the amine compound (a2) include the amino group itself. The groups derived from the N-substituted maleimide group of the maleimide resin (a1) include the N-substituted maleimide group itself.

### Production Method of Modified Maleimide Resin (A)

The modified maleimide resin (A) can be produced, for example, by reacting the maleimide resin (a1) and the amine compound (a2) in an organic solvent.

The reaction of the maleimide resin (a1) and the amine compound (a2) performed provides the modified maleimide resin (A) obtained through the Michael addition reaction of the maleimide resin (a1) and the amine compound (a2).

In the reaction of the maleimide resin (a1) and the amine compound (a2), a reaction catalyst may be used depending on necessity.

The reaction temperature of the Michael addition reaction is preferably 50 to 160° C., more preferably 60 to 150° C., and further preferably 70 to 140° C., from the standpoint of the workability, such as the reaction rate, the suppression of gelation of the product during the reaction, and the like.

The reaction time of the Michael addition reaction is preferably 0.5 to 10 hours, more preferably 1 to 8 hours, and further preferably 2 to 6 hours, from the standpoint of the productivity and the sufficient progress of the reaction.

However, these reaction conditions may be appropriately regulated depending on the kinds of the raw materials used and the like, and are not particularly limited.

### Content of Modified Maleimide Resin (A)

In the resin composition of the present embodiment, the content of the modified maleimide resin (A) is not particularly limited, and is preferably 5 to 70% by mass, more preferably 10 to 50% by mass, and further preferably 15 to 40% by mass, based on the total amount (100% by mass) of the resin components in the resin composition of the present embodiment.

In the case where the content of the modified maleimide resin (A) is the lower limit value or more, there is a tendency that the heat resistance, the moldability, the processability, and the adhesiveness to a conductor are further improved. In the case where the content of the modified maleimide resin (A) is the upper limit value or less, there is a tendency that the dielectric characteristics are further improved.

In the description herein, the “resin component” means a resin and a compound that forms a resin through curing reaction.

For example, in the resin composition of the present embodiment, the component (A) and the component (B) each correspond to the resin component.

In the case where the resin composition of the present embodiment contains a resin or a compound that forms a resin through a curing reaction as an optional component in addition to the aforementioned components, the optional component is included in the resin component. Examples of the optional component that corresponds to the resin component include the component (C) and the component (D) described later. On the other hand, the component (E) and the component (F) are not included in the resin component.

The total content of the resin components in the resin composition of the present embodiment is not particularly limited, and is preferably 10 to 60% by mass, more preferably 15 to 50% by mass, and further preferably 20 to 40% by mass, based on the total solid content (100% by mass) of the resin composition of the present embodiment, from the standpoint of the low thermal expansion, the heat resistance, the flame retardancy, and the adhesiveness to a conductor.

### Polymaleimide Resin (B)

The polymaleimide resin (B) is not particularly limited, as long as being a maleimide resin having three or more N-substituted maleimide groups.

One kind of the polymaleimide resin (B) may be used alone, or two or more kinds thereof may be used in combination.

The resin composition of the present embodiment is enhanced in desmear resistance of the cured product thereof with the component (B) contained. While the mechanism therefor is not clear, it is estimated that one of the contributory factors is that the cured product formed with the resin composition containing the component (B) has a crosslinked structure with a more complex three-dimensional structure, and thereby the desmear solution is prevented from penetrating thereto, or the dissolution thereby is prevented from occurring through entanglement of the molecules.

The number of the N-substituted maleimide groups that the polymaleimide resin (B) has may be 6 or less, may be 5 or less, or 4 or less, from the standpoint of the handleability.

The polymaleimide resin (B) is preferably a maleimide resin having three or more N-substituted maleimide groups that are bonded to the aromatic ring from the standpoint of the desmear resistance, the heat resistance, the low thermal expansion, and the elastic modulus.

The maleimide resin having three or more N-substituted maleimide groups that are bonded to the aromatic ring may have or may not have an N-substituted maleimide group that is bonded to the other position than the aromatic ring.

The polymaleimide resin (B) is preferably a compound represented by the following general formula (B-1).

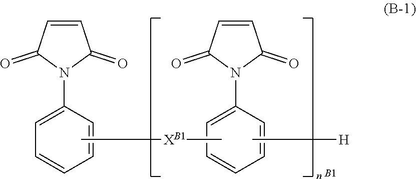

(In the formula, X^{B1} each independently represent a divalent hydrocarbon group having 1 to 20 carbon atoms, and n^{B1} represents an integer of 2 to 5.)

Examples of the divalent hydrocarbon group having 1 to 20 carbon atoms represented by X^{B1} in the general formula (B-1) include a divalent aliphatic hydrocarbon group, such as an alkylene group having 1 to 5 carbon atoms and an alkylidene group having 2 to 5 carbon atoms: and a divalent hydrocarbon group containing an aromatic hydrocarbon group represented by the following general formula (B-2).

Examples of the alkylene group having 1 to 5 carbon atoms include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and further preferably a methylene group.

The alkylidene group having 2 to 5 carbon atoms is preferably an alkylidene group having 2 to 4 carbon atoms, more preferably an alkylidene group having 2 or 3 carbon atoms, and further preferably an isopropylidene group.

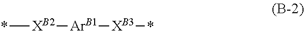

(In the formula, Ar^{B1} represents a divalent aromatic hydrocarbon group, X^{B2} and X^{B3} each independently represent a divalent aliphatic hydrocarbon group having 1 to 5 carbon atoms, and * represents a bonding site.)

Examples of the divalent aliphatic hydrocarbon group having 1 to 5 carbon atoms represented by X^{B2} and X^{B3} in the general formula (B-2) include the same groups as the alkylene group having 1 to 5 carbon atoms, the alkylidene group having 2 to 5 carbon atoms, and the like described for X^{B1} in the general formula (B-1). Among these, a methylene group is preferred.

Examples of the divalent aromatic hydrocarbon group represented by Ar^{B1} in the general formula (B-2) include a phenylene group, a naphthylene group, a biphenyldiyl group, and an anthracenediyl group. Among these, a biphenyldiyl group is preferred. Examples of the biphenyldiyl group include a 4,2′-biphenyldiyl group, a 4,3′-biphenyldiyl group, a 4,4′-biphenyldiyl group, and a 3,3′-biphenyldiyl group, in which a 4,4′-biphenyldiyl group is preferred.

Among the aforementioned options, X^{B1} in the general formula (B-1) preferably represents an alkylene group having 1 to 5 carbon atoms or an alkylidene group having 2 to 5 carbon atoms, more preferably a methylene group or an isopropylidene group, and further preferably a methylene group.

n^{B1} in the general formula (B-1) represents an integer of 2 to 5, preferably an integer of 2 to 4, and more preferably 2 or 3.

Examples of the compound represented by the general formula (B-1) include polyphenylmethane maleimide and biphenyl aralkyl type maleimide. Among these, polyphenylmethane maleimide is preferred from the standpoint of the desmear resistance, the heat resistance, the low thermal expansion, and the elastic modulus.

### Content of Polymaleimide Resin (B)

In the resin composition of the present embodiment, the content of the polymaleimide resin (B) is not particularly limited, and is preferably 5 to 80% by mass, more preferably 10 to 75% by mass, further preferably 20 to 70% by mass, and particularly preferably 30 to 65% by mass, based on the total amount (100% by mass) of the resin components in the resin composition of the present embodiment.

In the case where the content of the polymaleimide resin (B) is the lower limit value or more, there is a tendency that the desmear resistance, the heat resistance, the low thermal expansion, and the elastic modulus are further improved. In the case where the content of the polymaleimide resin (B) is the upper limit value or less, there is a tendency that the flowability of the resin composition is enhanced, and the moldability thereof can be easily improved.

The ratio of the content of the component (B) with respect to the content of the component (A) (component (B)/component (A)) based on mass is preferably 0.4 to 10, more preferably 0.6 to 7, and further preferably 0.8 to 5.

In the case where the ratio of the contents (component (B)/component (A)) is the lower limit value or more, there is a tendency that the desmear resistance, the heat resistance, the low thermal expansion, and the elastic modulus are further improved. In the case where the ratio of the contents (component (B)/component (A)) is the upper limit value or less, there is a tendency that the flowability of the resin composition is enhanced, and the moldability is further improved.

### Epoxy Resin (C)

The resin composition of the present embodiment preferably further contains an epoxy resin (C).

In the case where the resin composition of the present embodiment contains an epoxy resin (C), there is a tendency that the adhesiveness to a conductor is further improved while retaining the excellent heat resistance.

One kind of the epoxy resin (C) may be used alone, or two or more kinds thereof may be used in combination.

The epoxy resin (C) can be classified, for example, into a glycidyl ether type epoxy resin, a glycidyl amine type epoxy resin, and a glycidyl ester type epoxy resin. Among these, a glycidyl ether type epoxy resin is preferred.

The epoxy resin (C) can be classified into various epoxy resins depending on the difference in main skeleton.

Specifically, the epoxy resin can be classified, for example, into a bisphenol type epoxy resin, such as a bisphenol A type epoxy resin, a bisphenol F type epoxy resin, and a bisphenol S type epoxy resin: a novolac type epoxy resin, such as a bisphenol A novolac type epoxy resin, a bisphenol F novolac type epoxy resin, a phenol novolac type epoxy resin, a cresol novolac type epoxy resin, a biphenyl novolac type epoxy resin, and a naphthol novolac type epoxy resin: an aralkyl type epoxy resin, such as a phenol aralkyl type epoxy resin, a biphenyl aralkyl type epoxy resin, and a naphthol aralkyl type epoxy resin: a stilbene type epoxy resin: a naphthylene ether type epoxy resin: a biphenyl type epoxy resin: a dihydroanthracene type epoxy resin: an epoxy resin containing a saturated dicyclopentadiene skeleton: a cyclohexanedimethanol type epoxy resin: a spiro ring-containing epoxy resin: a heterocyclic epoxy resin: an alicyclic epoxy resin: an aliphatic chain epoxy resin: and a rubber-modified epoxy resin. Among these, an epoxy resin having a naphthalene structure is preferred from the standpoint of the heat resistance.

The epoxy group equivalent of the epoxy resin (C) is not particularly limited, and is preferably 80 to 600 g/mol, more preferably 100 to 400 g/mol, and further preferably 120 to 300 g/mol, from the standpoint of the heat resistance and the adhesiveness to a conductor.

### Content of Epoxy Resin (C)

In the case where the resin composition of the present embodiment contains the epoxy resin (C), the content of the epoxy resin (C) in the resin composition of the present embodiment is not particularly limited, and is preferably 1 to 50% by mass, more preferably 5 to 40% by mass, and further preferably 10 to 35% by mass, based on the total amount (100% by mass) of the resin components in the resin composition of the present embodiment, from the standpoint of the desmear resistance, the heat resistance, the low thermal expansion, the elastic modulus, and the adhesiveness to a conductor.

### Curing Agent (D)

The resin composition of the present embodiment preferably further contains a curing agent (D).

In the case where the resin composition of the present embodiment contains a curing agent (D), there is a tendency that the desmear resistance and the heat resistance are further improved.

One kind of the curing agent (D) may be used alone, or two or more kinds thereof may be used in combination.

Examples of the curing agent (D) include aromatic amines, such as dicyandiamide, 4,4′-diaminodiphenylmethane, 4,4′-diamino-3,3′-diethyl-diphenylmethane, 4,4′-diaminodiphenylsulfone, phenylenediamine, and xylenediamine: aliphatic amines, such as hexamethylenediamine and 2,5-dimethylhexamethylenediamine: a guanamine compound, such as melamine and benzoguanamine: a phenol resin, such as a phenol novolac resin, a cresol novolac resin, a phenol aralkyl resin, a naphthol aralkyl resin, a biphenyl-modified phenol resin, a biphenyl-modified naphthol resin, and aminotriazine novolac resin: a benzoxazine compound, such as P-d type benzoxazine: and an acid anhydride, such as phthalic anhydride, pyromellitic anhydride, maleic anhydride, and a maleic anhydride copolymer. Among these, aromatic amines and a benzoxazine compound are preferred.

### Content of Curing Agent (D)

In the case where the resin composition of the present embodiment contains the curing agent (D), the content of the curing agent (D) in the resin composition of the present embodiment is not particularly limited, and is preferably 1 to 40% by mass, more preferably 5 to 35% by mass, and further preferably 10 to 30% by mass, based on the total amount (100% by mass) of the resin components in the resin composition of the present embodiment, from the standpoint of the desmear resistance, the heat resistance, the low thermal expansion, the elastic modulus, and the adhesiveness to a conductor.

### Curing Accelerator (E)

The resin composition of the present embodiment preferably further contains a curing accelerator (E).

In the case where the resin composition of the present embodiment contains a curing accelerator (E), there is a tendency that the curability is enhanced, and the better dielectric characteristics, the better heat resistance, and the better adhesiveness to a conductor are easily obtained.

One kind of the curing accelerator (E) may be used alone, or two or more kinds thereof may be used in combination.

Examples of the curing accelerator (E) include an acidic catalyst, such as p-toluenesulfonic acid; an amine compound, such as triethylamine, tributylamine, pyridine, and dicyandiamide; an imidazole compound, such as methylimidazole, phenylimidazole, 1-cyanoethyl-2-phenylimidazole, and 1-cyanoethyl-2-phenylimidazolium trimellitate; an isocyanate-masked imidazole compound, such as an addition reaction product of a hexamethylene diisocyanate resin and 2-ethyl-4-methylimidazole; a quaternary ammonium compound; a phosphorus based compound, such as triphenylphosphine; an organic peroxide, such as dicumyl peroxide, 2,5-dimethyl-2,5-bis(t-butylperoxy)hexyne-3,2,5-dimethyl-2,5-bis (t-butylperoxy) hexane, t-butyl peroxyisopropyl monocarbonate, and α,α′-bis(t-butylperoxy)diisopropylbenzene; and a carboxylate salt of manganese, cobalt, zinc, or the like.

### Content of Curing Accelerator (E)

In the case where the resin composition of the present embodiment contains the curing accelerator (E), the content of the curing accelerator (E) in the resin composition of the present embodiment is not particularly limited, and is preferably 0.01 to 10% by mass, more preferably 0.05 to 5% by mass, and further preferably 0.1 to 1% by mass, based on the total amount (100% by mass) of the resin components in the resin composition of the present embodiment, from the standpoint that an appropriate curing rate can be easily obtained.

### Inorganic Filler (F)

The resin composition of the present embodiment preferably further contains an inorganic filler (F).

In the case where the resin composition of the present embodiment contains an inorganic filler (F), there is a tendency that the better low thermal expansion and the better heat resistance are easily obtained. One kind of the inorganic filler (F) may be used alone, or two or more kinds thereof may be used in combination.

Examples of the inorganic filler (F) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Among these, silica, alumina, mica, and talc are preferred, silica and alumina are more preferred, and silica is further preferred, from the standpoint of the low thermal expansion, the heat resistance, and the flame retardancy.

Examples of the silica include precipitated silica having a large water content produced by a wet method and dry silica having substantially no bound water or the like produced by a dry method. Examples of the dry silica include pulverized silica, fumed silica, and molten silica, depending on the production method. Among these, molten silica is preferred from the standpoint of the dispersibility and the moldability.

The average particle diameter (D₅₀) of the inorganic filler (F) is not particularly limited, and is preferably 0.01 to 20 μm, more preferably 0.1 to 10 μm, further preferably 0.2 to 1 μm, and particularly preferably 0.3 to 0.8 μm, from the standpoint of the dispersibility of the inorganic filler (F) and the achievement of fine wiring.

In the description herein, the average particle diameter (D₅₀) of the inorganic filler (F) is a particle diameter at the point corresponding to a volume of 50% on the cumulative frequency distribution curve of the particle diameter as the total volume of the particles being 100%. The average particle diameter of the inorganic filler (F) can be measured, for example, with a particle size distribution analyzer using a laser diffraction-scattering method or the like.

Examples of the shape of the inorganic filler (F) include a spherical shape and a pulverized shape, and a spherical shape is preferred.

In the resin composition of the present embodiment, a coupling agent may be used for the purpose of enhancing the dispersibility of the inorganic filler (F) and the adhesiveness between the inorganic filler (F) and the organic components. Examples of the coupling agent include a silane coupling agent and a titanate coupling agent.

### Content of Inorganic Filler (F)

In the case where the resin composition of the present embodiment contains the inorganic filler (F), the content of the inorganic filler (F) in the resin composition of the present embodiment is not particularly limited, and is preferably 40 to 90% by mass, more preferably 50 to 85% by mass, and further preferably 60 to 80% by mass, based on the total amount (100% by mass) of the solid content in the resin composition, from the standpoint of the low thermal expansion, the heat resistance, the moldability, and the adhesiveness to a conductor.

### Additional Components

The resin composition of the present embodiment may further contain, depending on necessity, one or more kinds of optional components selected from the group consisting of a resin material other than the aforementioned components, a flame retarder, an antioxidant, a thermal stabilizer, an antistatic agent, an ultraviolet ray absorbent, a pigment, a colorant, a lubricant, a silane coupling agent, an organic solvent, and additives other than these materials.

One kind of each of the optional components may be used alone, or two or more kinds thereof may be used in combination.

The content of the optional component in the resin composition of the present embodiment is not particularly limited, and the optional component may be used in such a range that does not impair the effects of the present embodiment, depending on necessity.

The resin composition of the present embodiment may not contain the aforementioned optional component depending on the desired capabilities thereof.

### Organic Solvent

The resin composition of the present embodiment may contain an organic solvent from the standpoint of enhancing the handleability and the standpoint of facilitating the production of the prepreg described later.

One kind of the organic solvent may be used alone, or two or more kinds thereof may be used in combination.

In the description herein, the resin composition containing an organic solvent may also be referred to as a varnish.

Examples of the organic solvent include an alcohol based solvent, such as ethanol, propanol, butanol, methyl cellosolve, butyl cellosolve, and propylene glycol monomethyl ether: a ketone based solvent, such as acetone, methyl ethyl ketone, methyl isobutyl ketone, and cyclohexanone; an ether based solvent, such as tetrahydrofuran; an aromatic hydrocarbon based solvent, such as toluene, xylene, and mesitylene; a nitrogen atom-containing solvent, such as dimethylformamide, dimethylacetamide, and N-methylpyrrolidone; a sulfur atom-containing solvent, such as dimethylsulfoxide; and an ester based solvent, such as y-butyrolactone.

Among these, an alcohol based solvent, a ketone based solvent, a nitrogen atom-containing solvent, and an aromatic hydrocarbon based solvent are preferred, an aromatic hydrocarbon based solvent is more preferred, and toluene is further preferred, from the standpoint of the solubility.

### Production Method of Resin Composition

The resin composition of the present embodiment can be produced by mixing the components described above.

In mixing the components, the components may be dissolved or dispersed under agitation. The conditions, such as the order of mixing the raw materials, the mixing temperature, and the mixing time, are not particularly limited, and may be optionally determined depending on the kinds of the raw materials and the like.

### Prepreg

The prepreg of the present embodiment is a prepreg including the resin composition of the present embodiment or a semi-cured product of the resin composition.

The prepreg of the present embodiment includes, for example, the resin composition of the present embodiment or a semi-cured product of the resin composition, and a sheet-like fiber substrate.

The sheet-like fiber substrate included in the prepreg of the present embodiment may be, for example, a known sheet-like fiber substrate having been used in various laminates for electric insulating materials.

Examples of the material of the sheet-like fiber substrate include inorganic fibers, such as E-glass, D-glass, S-glass, and Q-glass: organic fibers, such as polyimide, polyester, and tetrafluoroethylene: and a mixture thereof. The sheet-like fiber substrate may have, for example, such forms as a woven fabric, a nonwoven fabric, a roving, a chopped strand mat, and a surfacing mat.

The prepreg of the present embodiment can be produced, for example, in such a manner that the sheet-like fiber substrate is coated or impregnated with the resin composition of the present embodiment, which is then heated and dried to the B-stage.

The temperature and the time of the heating and drying are not particularly limited, and may be, for example, 50 to 200° C. and 1 to 30 minutes from the standpoint of the productivity and the formation of the resin composition of the present embodiment appropriately into the B-stage.

The content of the resin composition in the prepreg of the present embodiment is not particularly limited, and is preferably 20 to 90% by mass, more preferably 25 to 80% by mass, and further preferably 30 to 75% by mass, from the standpoint that the better moldability can be easily obtained in forming into a laminate.

### Resin Film

The resin film of the present embodiment is a resin film including the resin composition of the present embodiment or a semi-cured product of the resin composition.

The resin film of the present embodiment can be produced, for example, in such a manner that the resin composition of the present embodiment containing an organic solvent, i.e., the resin varnish, is coated on a support, and then heated and dried.

Examples of the support include a plastic film, a metal foil, and release paper.

The temperature and the time of the heating and drying are not particularly limited, and may be, for example, 50 to 200° C. and 1 to 30 minutes from the standpoint of the productivity and the formation of the resin composition of the present embodiment appropriately into the B-stage.

The resin film of the present embodiment is preferably used for forming an insulating layer in the production of a printed wiring board.

### Laminate

The laminate of the present embodiment is a laminate including a cured product of the resin composition of the present embodiment and a metal foil.

A laminate including a metal foil may also be referred to as a metal-clad laminate.

The metal of the metal foil is not particularly limited, and examples thereof include copper, gold, silver, nickel, platinum, molybdenum, ruthenium, aluminum, tungsten, iron, titanium, chromium, and an alloy containing one or more kinds of these metal elements.

The laminate of the present embodiment can be produced, for example, in such a manner that a metal foil is disposed on one surface or both surfaces of the prepreg of the present embodiment, which are then molded under heat and pressure.

In general, the prepreg in the B-stage is cured through the molding under heat and pressure, resulting in the laminate of the present embodiment.

In the molding under heat and pressure, only one ply of the prepreg may be used, or two or more plies of the prepregs may be laminated.

The molding under heat and pressure may be performed by multi-stage press, multi-stage vacuum press, continuous molding, autoclave molding, or the like.

The condition of the molding under heat and pressure is not particularly limited, and may be, for example, a temperature of 100 to 300° C., a period of time of 10 to 300 minutes, and a pressure of 1.5 to 5 MPa.

### Printed Wiring Board

The printed wiring board of the present embodiment is a printed wiring board including a cured product of the resin composition of the present embodiment.

The printed wiring board of the present embodiment can be produced, for example, by forming a conductor circuit by a known method on one or more kinds selected the group consisting of a cured product of the prepreg of the present embodiment, a cured product of the resin film of the present embodiment, and the laminate. Furthermore, depending on necessity, a multilayer printed wiring board can be produced by adhering to form a multilayer structure. The conductor circuit can be formed, for example, by appropriately performing drilling, metal plating, etching of the metal foil, and the like.

### Semiconductor Package

The semiconductor package of the present embodiment is a semiconductor package including the printed wiring board of the present embodiment and a semiconductor device.

The semiconductor package of the present embodiment can be produced, for example, by mounting a semiconductor chip, a memory device, and the like by a known method on the printed wiring board of the present embodiment.

### EXAMPLES

The present embodiment will be described specifically with reference to examples below. However, the present embodiment is not limited to the examples below.

In the examples, the number average molecular weight (Mn) was measured in the following manner.

The number average molecular weight was measured by gel permeation chromatography (GPC) and calculated with a calibration curve using the standard polystyrene. The calibration curve was approximated by the tertiary method using the standard polystyrene (TSKstandard Polystyrene (Type: A-2500, A-5000, F-1, F-2, F-4, F-10, F-20, F-40) (trade names, available from Tosoh Corporation). The measurement condition of GPC is shown below.

### Apparatus

Pump: L-6200 (available from Hitachi High-Technologies, Inc.)
Detector: L-3300 RI (available from Hitachi High-Technologies, Inc.)
Column oven: L-655A-52 (available from Hitachi High-Technologies, Inc.)
Columns: guard column: TSK Guardcolumn HHR-L+column: TSKgel G4000HHR+TSKgel G2000HHR (trade names, all available from Tosoh Corporation)
Column size: 6.0×40 mm (guard column), 7.8×300 mm (column)
Eluent: tetrahydrofuran
Specimen concentration: 30 mg/5 ml
Injection amount: 20 μL
Flow rate: 1.00 mL/min
Measurement temperature: 40° C.

### Production Examples 1 to 5

### Production of Modified Maleimide Resins A-A to A-E

60 parts by mass of propylene glycol monomethyl ether and the components shown in Table 1 according to the raw material composition shown in Table 1 were placed in a heatable and coolable reaction vessel having a capacity of 5 L equipped with a thermometer, an agitation device, and a moisture analyzer with a reflux condenser. The resulting solution was reacted under refluxing for 2 hours, resulting in each of the solutions of the modified maleimide resins A-A to A-E having a solid concentration of 40% by mass. The unit for the numerals shown in the raw material compositions in Table 1 is part by mass.

### Examples 1 to 10 and Comparative Example 1

### Production of Resin Composition

The components shown in Table 2 according to the composition shown in Table 2 were mixed, and mixed and agitated with 58 parts by mass of toluene and 10 parts by mass of methyl isobutyl ketone at room temperature (25° C.), thereby producing resin compositions having a solid concentration of 55 to 65% by mass. The unit for the numerals shown in the compositions in Table 2 is part by mass, and for the solution, part by mass in terms of solid content.

### Production of Double-sided Copper-clad Laminate

The resin composition obtained above was coated on a glass cloth having a thickness of 0.1 mm (T-glass, available from Nitto Boseki Co., Ltd.), and then heated and dried at 130° C. for 5 minutes, thereby producing a prepreg having a content of the resin composition of about 50% by mass. Four plies of the prepregs were laminated, and on the upper and lower surfaces thereof, copper foils having a thickness of 12 μm (“3EC-M3-VLP-12”, trade name, available from Mitsui Mining And Smelting Co., Ltd., Rz of M surface: 3.0 μm) were disposed in such a manner that the M surface was in contact with the prepreg. The resulting laminate was molded under heat and pressure at a temperature of 240° C. and a pressure of 3.0 MPa for a period of time of 90 minutes, resulting in a double-sided copper-clad laminate (thickness: 0.43 mm).

### Evaluation Methods

The double-sided copper-clad laminates obtained in the examples were evaluated in the following manner. The results are shown in Table 2.

### Measurement of Copper Foil Peel Strength

The copper foil of the double-sided copper-clad laminate obtained in each of the examples was etched to a linear line form having a width of 3 mm, which was designated as a test piece. The copper foil in the form of a linear line mounted on Compact Table-Top Universal/Tensile Tester (“EZ-TEST”, trade name, available from Shimadzu Corporation), and measured for the copper foil peel strength by peeling in the 90° direction at room temperature (25° C.) according to JIS C6481:1996. The tensile rate in peeling the copper foil was 50 mm/min.

### Measurement of Glass Transition Temperature and Thermal Expansion Coefficient

The double-sided copper-clad laminate obtained in each of the examples was immersed in a copper etching solution to remove the copper foil, and a 5-mm square test piece was prepared. The test piece was measured for the glass transition temperature and the thermal expansion coefficient with a thermomechanical analyzer (TMA) (Q400 (model number), available from TA Instruments Japan, Inc.) according to the Institute for Interconnecting and Packaging Electronic Circuits (IPC) standard. The thermal expansion coefficient shown in Table 2 is the thermal expansion coefficient in the plane direction, and means the average value of the thermal expansion coefficients in a temperature range of 30 to 100° C. A thermal expansion coefficient of 7.0 ppm/° C. or less was judged as having sufficient low thermal expansion.

### Measurement of 50° C. Tensile Elastic Modulus E′

The double-sided copper-clad laminate obtained in each of the examples was immersed in a copper etching solution to remove the copper foil, and a test piece of 4 mm×40 mm with the copper foil removed was prepared. The test piece was measured for the tensile elastic modulus E′ at 50° C. with a dynamic mechanical analyzer (DMA) (Q800 (model number), available from TA Instruments Japan, Inc.) at a span of 20 mm, a frequency of 10 Hz, and a vibration displacement of 5 μm.

### Measurement of Desmear Weight Reduction Rate

The double-sided copper-clad laminate obtained in each of the examples was immersed in a copper etching solution to remove the copper foil, and an evaluation substrate of 40 mm×40 mm with the copper foil removed was prepared. The evaluation substrate was treated with a swelling solution “Swelling Dip Securiganth P” (available from Atotech Japan K. K.) at 70° C. for 5 minutes. Subsequently, the evaluation substrate was rinsed with water at room temperature for 2 minutes, and then roughened by treating with a roughening solution “Concentrate Compact CP” (available from Atotech Japan K.K.) at 80° C. for 10 minutes or 15 minutes. Thereafter, the evaluation substrate was rinsed with water at 50° C. for 2 minutes, then neutralized with a neutralizing solution “Reduction Solution Securiganth P500” (available from Atotech Japan K.K.) at 40° C. for 5 minutes, and then rinsed with water at room temperature for 5 minutes, followed by drying.

The desmear weight reduction rate was calculated from the dry weight before the desmear treatment and the difference from the dry weight after the desmear treatment (dry weight before desmear treatment-dry weight after desmear treatment).

TABLE 1

| | | | Production Example | | | | |
|---|---|---|---|---|---|---|---|
| | | | 1 | 2 | 3 | 4 | 5 |
| Kind of modified maleimide resin | | | A-A | A-B | A-C | A-D | A-E |
| Raw material | Maleimide | polyphenylmethane maleimide | 100 | | | | 100 |
| composition | resin (a1) | 3,3′-dimethyl-5,5′-diethyl- | | 100 | | | |
| | | 4,4′-diphenylmethanebismaleimide | | | | | |
| | | 2,2-bis[4-(4- | | | 100 | 100 | |
| | | maleimidophenoxy)phenyl]propane | | | | | |
| | Amine | polydimethylsiloxane having | 75 | 75 | 75 | 100 | 30 |
| | compound (a2) | primary amino groups at both ends | | | | | |

TABLE 2

| | | | | | | | | | | | | | Compar- |
|---|---|---|---|---|---|---|---|---|---|---|---|---|---|
| | | | | | | | | | | | | | ative |
| | | | Example | | | | | | | | | | Example |
| | | | 1 | 2 | 3 | 4 | 5 | 6 | 7 | 8 | 9 | 10 | 1 |
| Composition | Compo- | Modified | 8 | 8 | | | | | | | | | |
| of resin | nent (A) | maleimide | | | | | | | | | | | |
| composition | | resin A-A | | | | | | | | | | | |
| | | Modified | | | 9 | | | | | | | | |
| | | maleimide | | | | | | | | | | | |
| | | resin A-B | | | | | | | | | | | |
| | | Modified | | | | 8 | 8 | 9 | 8 | | 12 | | |
| | | maleimide | | | | | | | | | | | |
| | | resin A-C | | | | | | | | | | | |
| | | Modified | | | | | | | | 10 | | | |
| | | maleimide | | | | | | | | | | | |
| | | resin A-D | | | | | | | | | | | |
| | | Modified | | | | | | | | | | 15 | 34 |
| | | maleimide | | | | | | | | | | | |
| | | resin A-E | | | | | | | | | | | |
| | Compo- | Polyphenyl- | 24 | 16 | 21 | 24 | 24 | 21 | 16 | 18 | | 24 | |
| | nent (B) | methane | | | | | | | | | | | |
| | | maleimide | | | | | | | | | | | |
| | | Biphenyl | | | | | | | | | 12 | | |
| | | aralkyl type | | | | | | | | | | | |
| | | maleimide | | | | | | | | | | | |
| | Compo- | Naphthol cresol | | | | | | | | | | 10 | 15 |
| | nent (C) | novolac type | | | | | | | | | | | |
| | | epoxy resin | | | | | | | | | | | |
| | | Naphthalene | 8 | | 6 | | | 6 | 6 | | 10 | | |
| | | type epoxy | | | | | | | | | | | |
| | | resin 1 | | | | | | | | | | | |
| | | Naphthalene | | 6 | | | 8 | | | | | | |
| | | type epoxy | | | | | | | | | | | |
| | | resin 2 | | | | | | | | | | | |
| | | Naphthalene | | | | 8 | | | | 6 | | | |
| | | type epoxy | | | | | | | | | | | |
| | | resin 3 | | | | | | | | | | | |
| | | Naphthalene | | | | | | | | | | | |
| | | type epoxy | | | | | | | | | | | |
| | | resin 4 | | | | | | | | | | | |
| | Compo- | 4,4′-Diamino- | | 10 | | | | 6 | | 6 | 6 | | |
| | nent (D) | diphenylsulfone | | | | | | | | | | | |
| | | P-d type | | | 6 | | | | 10 | | | | |
| | | Benzoxazine | | | | | | | | | | | |
| | Compo- | G-8009L | 0.2 | 0.1 | 0.1 | 0.2 | 0.2 | 0.1 | 0.1 | 0.1 | 0.1 | 0.1 | 0.1 |
| | nent (E) | | | | | | | | | | | | |
| | Compo- | Molten silica | 100 | 100 | 100 | 100 | 100 | 100 | 100 | 100 | 100 | 100 | 100 |
| | nent (F) | | | | | | | | | | | | |

| | | | | | | | | | | | | |
|---|---|---|---|---|---|---|---|---|---|---|---|---|
| Evaluation | Cooper foil peel | 0.62 | 0.73 | 0.65 | 0.63 | 0.80 | 0.66 | 0.82 | 0.80 | 0.79 | 0.62 | 0.74 |
| result | strength (kN/m) | | | | | | | | | | | |
| | Glass transition | 330 | >360 | >360 | >360 | >360 | 316 | 356 | 344 | 301 | >360 | 295 |
| | temperature (° C.) | | | | | | | | | | | |
| | Thermal expansion | 5.8 | 6.2 | 6.1 | 6.1 | 5.7 | 5.8 | 5.0 | 5.1 | 7.0 | 6.4 | 7.2 |
| | coefficient | | | | | | | | | | | |
| | (ppm/° C.) | | | | | | | | | | | |
| | 50° C. Tensile | 29 | 28 | 27 | 28 | 29 | 28 | 28 | 28 | 25 | 28 | 24 |
| | elastic modulus | | | | | | | | | | | |
| | E′ (GPa) | | | | | | | | | | | |
| | Desmear weight | 2.9 | 3.3 | 1.5 | 2.0 | 2.2 | 2.3 | 2.5 | 2.2 | 2.2 | 2.4 | 3.7 |
| | reduction rate (g/m²) | | | | | | | | | | | |
| | roughening treatment | | | | | | | | | | | |
| | time: 10 minutes | | | | | | | | | | | |
| | Desmear weight | 4.0 | 4.5 | 2.0 | 3.0 | 3.2 | 3.2 | 3.0 | 3.5 | 3.5 | 3.8 | 5.9 |
| | reduction rate (g/m²) | | | | | | | | | | | |
| | roughening treatment | | | | | | | | | | | |
| | time: 15 minutes | | | | | | | | | | | |

The details of the materials in Tables 1 and 2 are as follows.

### Maleimide Resins (a1) in Table 1 and Component (B) in Table 2

Polyphenylmethane maleimide: available from Daiwa Kasei Industry Co., Ltd., trade name: “BMI-2300”, a compound represented by the general formula (B-1), in which X^{B1} represents a methylene group
Biphenyl aralkyl type maleimide: available from Nippon Kayaku Co., Ltd., trade name: “MIR-3000”, a compound represented by the general formula (B-1), in which X^{B1} represents a divalent hydrocarbon group represented by the general formula (B-2), in which X^{B2} and X^{B3} represent methylene groups, and Ar^{B1} represents a 4,4′-biphenyldiyl group

### Amine Compound (a2)

Polydimethylsiloxane having primary amino groups at both ends: available from Momentive Performance Materials Japan LLC, trade name: “XF42-C5379”, primary amino group equivalent: 740 g/mol

### Component (A)

Modified maleimide resins A-A to A-E: modified maleimide resins A-A to A-E produced in Production Examples 1 to 5

### Component (C)

Naphthol cresol novolac type epoxy resin: epoxy group equivalent: 230 g/mol, available from Nippon Kayaku Co., Ltd., trade name: “NC-7000L”
Naphthalene type epoxy resin 1: epoxy group equivalent: 250 g/mol, available from DIC Corporation, trade name: “HP-6000”
Naphthalene type epoxy resin 2: epoxy group equivalent: 143 g/mol, available from DIC Corporation, trade name: “HP-4032SS”
Naphthalene type epoxy resin 3: epoxy group equivalent: 230 g/mol, available from DIC Corporation, trade name: “HP-9540”
Naphthalene type epoxy resin 4: available from DIC Corporation, trade name: “EXA-7311-G4”

### Component (D)

P-d type benzoxazine: 3,3′-(methylene-1,4-diphenylene)bis(3,4-dihydro-2H-1,3-benzoxazine)

### Component (E)

G-8009L: addition reaction product of hexamethylene diisocyanate resin and 2-ethyl-4-methylimidazole

### Component (F)

Molten silica: average particle diameter (D₅₀): 0.5 μm

It is understood from the results shown in Table 2 that the cured products molded from the resin compositions of Examples 1 to 10 of the present embodiment have a smaller desmear weight reduction rate and is excellent in desmear resistance than the cured product molded from the resin composition of Comparative Example 1 that does not contain the component (B).

### INDUSTRIAL APPLICABILITY

The cured product produced from the resin composition of the present embodiment is excellent in desmear resistance, and therefore the prepreg, the laminate, the printed wiring board, the semiconductor package, and the like obtained by using the resin composition are favorably applied particularly to electronic components handling high frequency signals.

1. A resin composition comprising
(A) a resin containing a structure derived from a maleimide resin (a) having one or more N-substituted maleimide groups, and a structure derived from an amine compound (b) having one or more amino groups, and
(B) a maleimide resin having three or more N-substituted maleimide groups.

2. The resin composition according to claim 1, wherein the amine compound (b) having one or more amino groups is a siloxane compound having one or more amino groups.

3. The resin composition according to claim 1, wherein the component (B) is a maleimide resin having three or more N-substituted maleimide groups that are bonded to an aromatic ring.

4. The resin composition according to claim 3, wherein the maleimide resin having three or more N-substituted maleimide groups that are bonded to the aromatic ring is a maleimide resin represented by the following general formula (B-1): 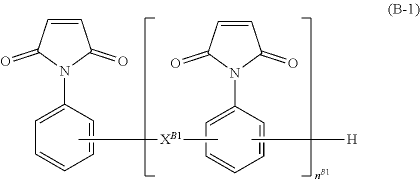
wherein X^{B1} represents a divalent hydrocarbon group having 1 to 20 carbon atoms, and n^{B1} represents an integer of 2 to 5.

5. The resin composition according to claim 4, wherein, in the general formula (B-1), X^{B1} represents an alkylene group having 1 to 5 carbon atoms or an alkylidene group having 2 to 5 carbon atoms.

6. The resin composition according to claim 1, wherein the resin composition has a ratio of the content of the component (B) with respect to the content of the component (A) (component (B)/component (A)) based on mass of 0.4 to 10.

7. The resin composition according to claim 1, wherein the resin composition further comprises (C) an epoxy resin.

8. A prepreg comprising the resin composition according to claim 1 or a semi-cured product of the resin composition.

9. A laminate comprising a cured product of the resin composition according to claim 1 and a metal foil.

10. A resin film comprising the resin composition according to claim 1 or a semi-cured product of the resin composition.

11. A printed wiring board comprising a cured product of the resin composition according to claim 1.

12. A semiconductor package comprising the printed wiring board according to claim 11 and a semiconductor device.
